(19) United States
(12) Patent Application Publication
(10) Pub. No.: US 2011/0266672 A1
(43) Pub. Date: Nov. 3, 2011

(54) INTEGRATED-CIRCUIT ATTACHMENT STRUCTURE WITH SOLDER BALLS AND PINS

(76) Inventor: Jeffrey Scott Sylvester, Tomball, TX (US)

(21) Appl. No.: 13/142,469

(22) PCT Filed: Jan. 30, 2009
(86) PCT No.: PCT/US09/32757

§ 371 Date: Jun. 28, 2011

(51) Int. Cl. H01L 23/498; B23K 31/02

(52) U.S. Cl. 257/738; 228/179.1; 257/E23.069

(57) ABSTRACT

An integrated-circuit attachment structure comprises an integrated circuit and a package assembly. The package assembly includes a package containing the integrated circuit. The package has pins at its corners and a grid at least primarily of solder halls on its bottom face.

### BACKGROUND

Integrated circuits are typically mounted on printed-circuit boards using either pin grid, arrays or solder ball arrays. Pin grid arrays came earlier, providing, secure physical and electrical connections. However, since the pins extend through holes in a printed circuit, they consume area on every layer of a printed-circuit board. Solder ball arrays bond to bonding pads on a top layer, leaving lower layers intact, easing routing constraints for conductors on those lower layers.

### BRIEF DESCRIPTION OF THE DRAWINGS

FIG. 1 is a schematic combination bottom and cut-away view of a first integrated circuit attachment structure in accordance with an embodiment of the invention. In the bottom-view portion of FIG. 1, clotted lines define a cross and a diamond that define quadrants and corner areas of the bottom face of an IC package. The dotted lines do not represent physical features.

FIG. 2 is a flow chart of a method of assembling an integrated attachment structure such as that of FIG. 1.

FIG. 3 is a schematic diagram of a second integrated circuit attachment structure in accordance with an embodiment of the invention.

FIG. 4 is a schematic diagram of a third integrated, circuit attachment structure in accordance with an embodiment of the invention.

FIG. 5 is a flow chart of an alternative method of assembling an integrated attachment structure.

### DETAILED DESCRIPTION

Embodiments of the present invention provide for integrated-circuit (IC) packages with both solder halls and pins. The solder balls provide for most of the physical and electrical connections between the IC package and a printed-circuit board (PCB), while pin connections are used at the corners of the IC package. The combined use of solder balls and pins addresses a problem identified by the inventors: to the extent they fail (e.g., due to flexing of a PCB). solder ball connections fail first at the corners of a solder hall grid. Using pin connections at the package largely eliminates this problem.

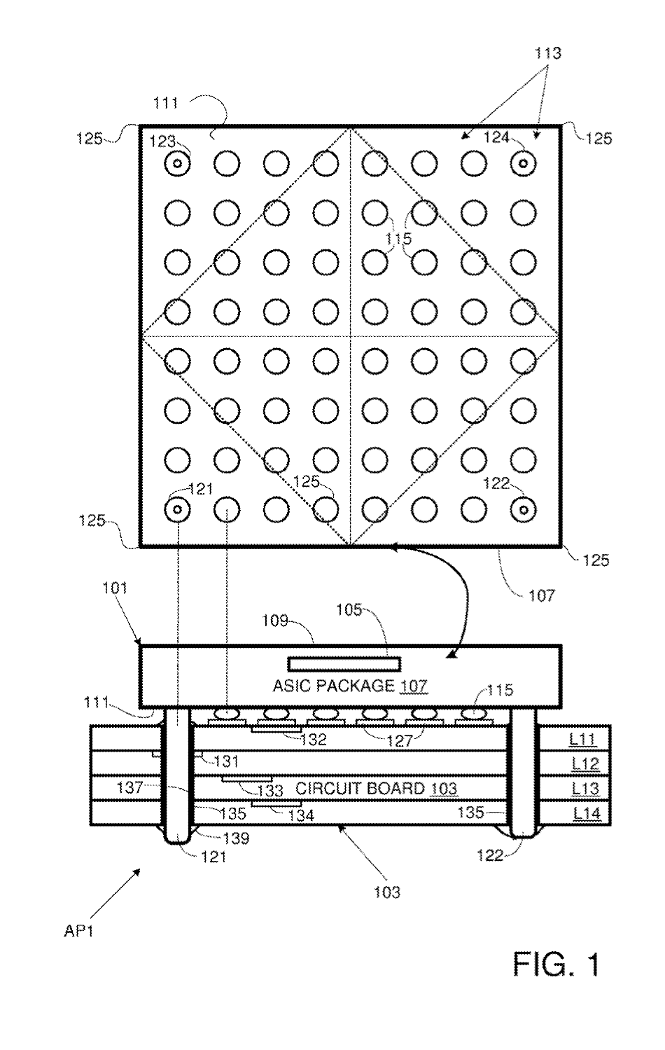

Thus, an IC attachment structure AP1 includes an IC package assembly 101 and a circuit hoard 103, in this case a PCB, as shown in FIG. 1. IC package assembly 101 includes an application-specific integrated circuit (ASIC) 105 and a package 107. Package 107 is a rectangular parallelepiped with a square top face 109 and a square bottom face 111. In alternative embodiments, the top and bottom faces of a package define non-square rectangles; other embodiments provide for other package geometries as well.

Bottom face 111 supports what is essentially an array of two-dimensional square array 113 of solder balls 115, with straight pins 121-1124 replacing solder balls at bottom-face corners 125. Package 107 provides for electrical connections between each hall 115 and pm 121 to integrated circuit 105. No such electrical connection is provided for pins 122-124. In an alternative embodiment, a package provides electrical connections for all pins to the integrated circuit; in another embodiment, none of the pins are electrically connected to the integrated circuit.

Circuit board 103 is shown with a flexible substrate having layers L11-L14; alternative embodiments can have more or fewer layers. Circuit board. 103 bears bonding pads 127 and conductors 131-134. Each pin 121-124 of package 107 is inserted into a respective hole 135 through circuit board 103 and held there in place by solder 137, including fillets 139. Embodiments of the invention provide for using zero, some, or all pins as electrical connections. In the illustrated embodiment, pin 121 makes electrical contact with a conductor 131 of second layer L12 so that, during use, it can be used for transferring power or signals between IC 105 and circuit board 103. On the other hand, no such conductors contact pins 122-124, which are thus used only to reinforce physical connections between package 107 and circuit board 103 to provide strain relief for the bonds between solder balls 113 and bonding pads 127.

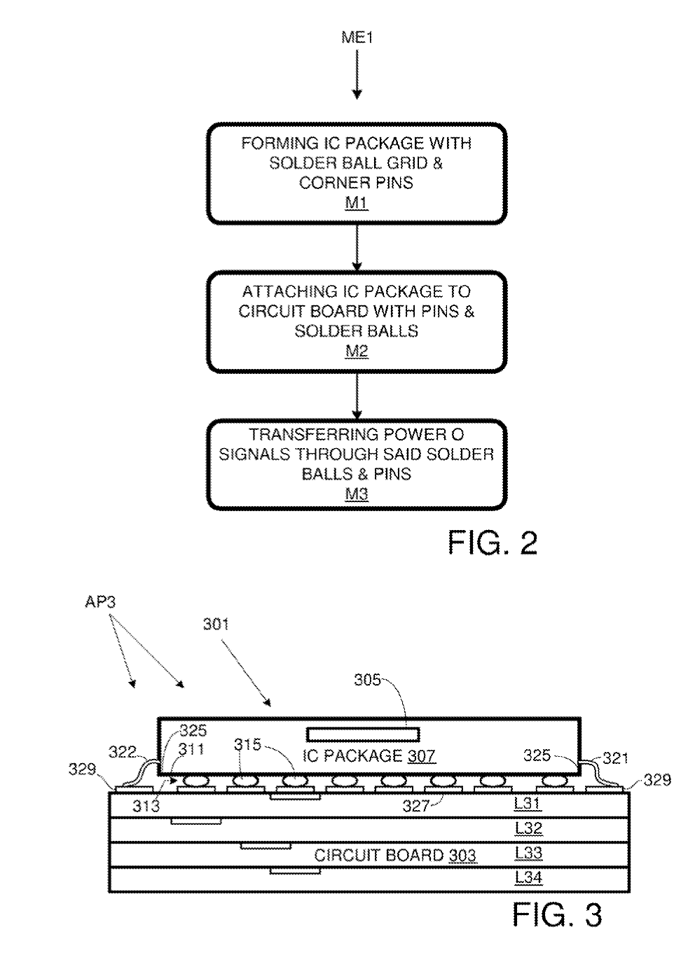

A method ME1 in accordance with an embodiment of the invention is flow charted in FIG. 2. At method segment M1, an IC package assembly is formed with a solder ball grid and corner pins. At method segment M2, the package assembly is attached to circuit board. When method ME1 is applied using structures such as those of FIG. 1, this can involve inserting straight pins through holes through a circuit board. The solder balls can be fused and pins can then be soldered to form physical and electrical connections between the package assembly and the circuit board. At method segment M3, during operation electrical power and signals are transferred between an integrated circuit of the package assembly and the circuit board. Depending on the embodiment, zero, one, some, or all pins may be used for transfer of power or signals; pins not so used are used for physical connections and not as electrical pathways.

In a variation of method ME1 method segment M2 involves bonding gull-wing type pins to bonding pads outside the perimeter of a package bottom face (whereas, in structure AP1, the pins are attached within the perimeter of bottom face 111). Such a method results in an IC attachment structure AP3 as shown in FIG. 3.

Accordingly, as shown in FIG. 3 IC attachment structure AP3 includes an integrated circuit package assembly 301 and a circuit board 303. Assembly 301 includes an integrated circuit 305 and a package 307. Package 307 has a bottom face 311 1 that bears a square array 313 of solder balls 316. In addition, package 307 bears gull-wing pins 321 and 322 at its corners 325.

Circuit board 303 has layers L31-L34; layer L31 includes “inside perimeter” (of bottom face 311) bonding pads solder balls and “outside perimeter” bonding pads 329. Solder balls 315 are bonded to “inside perimeter” bonding pads 327. Gull-wing pins 321 and 322 are bonded to “outside perimeter” surface mount bonding pads 329 to provide strain relief for solder ball connections to bonding pads 327. Gull-wing pin 321 provides for transferring power or signals between integrated circuit 305 and circuit board 303, while gull-wing pin 322 does not. Variants of this embodiment can use zero to all (e.g., four) gull-wing pins for power or signal transfers between an integrated, circuit and a circuit board.

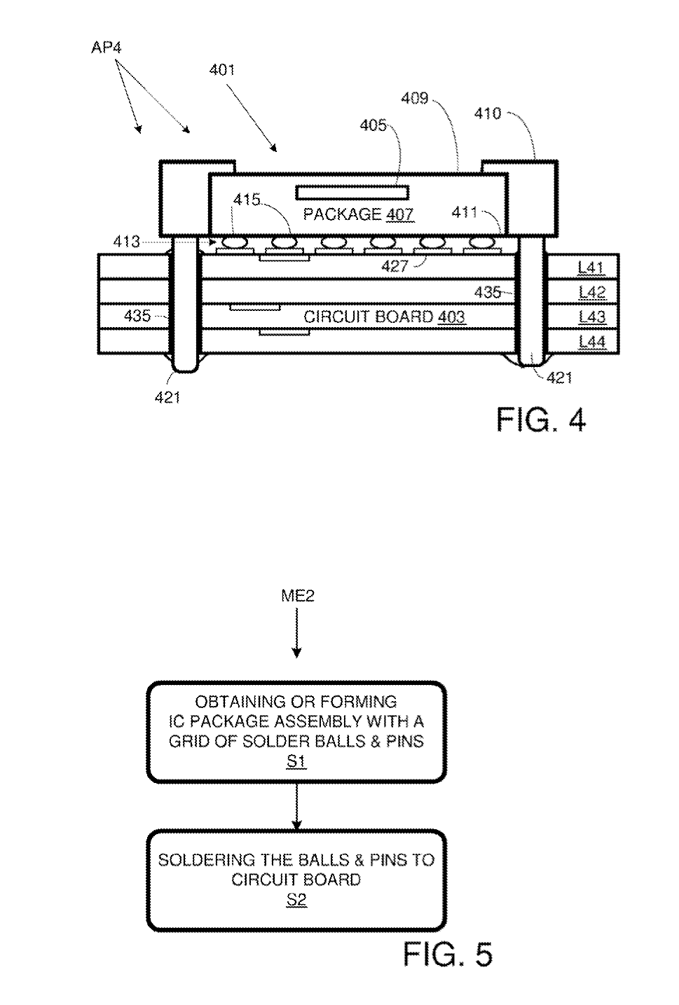

A further embodiment provides for an IC attachment structure in which pins are attached directly to a bracket rather than directly to a package. In this case, integrated circuit attachment structure AP4 includes an IC package assembly 401 and a circuit board 403, as shown in FIG. 4. Assembly 401 includes an integrated circuit 405, a package 407, and a bracket 410, Package 407 has a bottom face 411 bearing a full (no corner substitutions) square array 413 of solder balls 415.

Solder balls 415 bond to surface mount bonding pads 427 of circuit board 403. Straight pins 421 of bracket 41.0 extend through outside perimeter holes 435 of circuit board 403 and are soldered in place. In this case, pins are used for strain relief rather than for power or data transfer. Also, pins 421 are outside the perimeter of bottom face 411 of package 407.

Part of bracket 410 grips the top surface 409 of package 407, holding package 407 in place and effecting proper alignment of pins 421 with solder balls 415. Most of package top 409 is exposed through bracket 410 to allow for heat radiation or attachment of a heat sink.

FIG. 5 is a flow chart of an alternative IC attachement method ME2. Method segment S1 provides for obtaining or forming an IC package assembly with a grid of solder balls and pins. Method segment S2 provides for soldering the halls and pins to a circuit board. These and other variations upon and modifications to the illustrated embodiment are within the scope of the invention as defined by the following claims.

What is claimed is:

1. An integrated-circuit attachment: structure comprising:
an integrated circuit;
a package assembly including a package containing said integrated circuit, said package having a bottom face, said bottom face having corners, said package including a grid at least primarily of solder balls at said face, said package assembly including pins at said corners.

2. An integrated-circuit attachment structure as recited in claim 1 wherein said pins are straight pins.

3. An integrated-circuit attachment structure as recited in claim 2 wherein said pins are attached to said package.

4. An integrated-circuit package as recited in claim 3 further comprising a circuit board having through holes into which said straight pins are inserted and soldered.

5. An integrated-circuit package as recited in claim 4 wherein at least one of said pins provides for transferring power or signals between said integrated circuit and said circuit board.

6. An integrated-circuit attachment structure as recited in claim 2 wherein said straight pins number exactly four.

7. An integrated-circuit attachment structure as recited in claim 1 wherein said pins are gull-wing type pins attached to said. package.

8. An integrated-circuit attachment structure as recited in claim 7 further comprising a circuit board having plural layers including a top layer and other layers, said top layer having bonding pads, said solder balls being soldered to at least some of said bonding pads, said pins being soldered to others of said bonding pads.

9. An integrated-circuit attachment structure as recited, in claim 1 wherein said package assembly also includes a bracket for mounting on said package, said bracket including said pins.

10. An integrated-circuit attachment structure as recited in claim 7 further comprising a circuit board, said circuit board having through holes into which said straight pins are inserted and soldered so that said bracket is attached to said package,

11. An integrated-circuit attachment method comprising:
obtaining or forming an integrated-circuit package assembly having a grid of solder balls and pins;
soldering said balls and pins to a circuit board.

12. An integrated-circuit attachment method as recited in claim 11 further comprising transferring power or signals between said, integrated-circuit package and said printed-circuit board through at least one of said pins.

13. An integrated-circuit attachment method as recited in claim 11 further comprising transferring power or signals between said integrated-circuit package and said printed-circuit board through said bails but not through said pins.

14. An integrated-circuit attachment method as recited in claim 11 wherein said soldering involves soldering said pins into holes in said circuit board

15. An integrated-circuit attachment method as recited in claim 11 wherein said soldering involves soldering said pins onto surface-mount pads on said printed-circuit board.
